(19) United States
(12) Patent Application Publication
(10) Pub. No.: US 2009/0032873 A1
(43) Pub. Date: Feb. 5, 2009

(54) Ultra thin single crystalline semiconductor TFT and process for making same

(76) Inventors: Jeffrey Scott Cites, Horseheads, NY (US); Jin Jang, Jamwon-dong (KR); ChuanChe Wang, Horseheads, NY (US); Carlo Anthony Kosik Williams, Painted Post, NY (US); Sung Eun Ahn, Painted Post, NY (US)

Correspondence Address: CORNING INCORPORATED, SP-TI-3-1, CORNING, NY, 14831, US

(21) Appl. No.: 11/895,125

(22) Filed: Aug. 23, 2007

Related U.S. Application Data
(60) Provisional application No. 60/962,522, filed on Jul. 30, 2007.

(51) Int. Cl. H01L 29/786; H01L 21/336

(52) U.S. Cl. 257/347; 438/151; 257/E21.415; 257/E29.273

(57) ABSTRACT

Methods and apparatus for producing a semiconductor on glass (SiOG) structure include: subjecting an implantation surface of a donor single crystal semiconductor wafer to an ion implantation process to create an exfoliation layer of the donor semiconductor wafer; bonding the implantation surface of the exfoliation layer to a glass substrate using electrolysis; separating the exfoliation layer from the donor semiconductor wafer, thereby exposing a cleaved surface of the exfoliation layer; subjecting the cleaved surface of the exfoliation layer to a dry etching process to produce a single crystal semiconductor layer of about 5-20 nm thickness; and forming a thin film transistor in the thin semiconductor layer.

### CROSS-REFERENCE TO RELATED APPLICATIONS

This application is a continuation of and claims the benefit of priority to Provisional Patent Application No. 60/962,522, filed on 30 Jul. 2007, the content of which is relied upon and incorporated herein by reference in its entirety.

### BACKGROUND

The present invention relates to the manufacture of thin film transistors (TFTs) on a semiconductor-on-insulator (SOI) structure using an improved process for making same.

To date, the semiconductor material most commonly used in semiconductor-on-insulator structures has been silicon. Such structures have been referred to in the literature as silicon-on-insulator structures and the abbreviation “SOI” has been applied to such structures. SOI technology is becoming increasingly important for high performance thin film transistors, solar cells, and displays, such as, active matrix displays. SOI structures may include a thin layer of substantially single crystal silicon (generally 0.1-0.3 microns in thickness but, in some cases, as thick as 5 microns) on an insulating material. The state of the art processes for forming TFTs on polysilicon result in silicon thicknesses on the order of about 50 nm. Among the limiting factors on the thinness of the silicon in a polysilicon TFT is existence of grain boundaries in the silicon structure.

For ease of presentation, the following discussion will at times be in terms of SOI structures. The references to this particular type of SOI structure are made to facilitate the explanation of the invention and are not intended to, and should not be interpreted as, limiting the invention's scope in any way. The SOI abbreviation is used herein to refer to semiconductor-on-insulator structures in general, including, but not limited to, silicon-on-insulator structures. Similarly, the SiOG abbreviation is used to refer to semiconductor-on-glass structures in general, including, but not limited to, silicon-on-glass structures. The SiOG nomenclature is also intended to include semiconductor-on-glass-ceramic structures, including, but not limited to, silicon-on-glass-ceramic structures. The abbreviation SOI encompasses SiOG structures.

Various ways of obtaining SOI structures wafer include epitaxial growth of silicon (Si) on lattice matched substrates. An alternative process includes the bonding of a single crystal silicon wafer to another silicon wafer on which an oxide layer of SiO₂ has been grown, followed by polishing or etching of the top wafer down to, for example, a 0.05 to 0.3 micron layer of single crystal silicon. Further methods include ion-implantation methods in which either hydrogen or oxygen ions are implanted either to form a buried oxide layer in the silicon wafer topped by Si in the case of oxygen ion implantation or to separate (exfoliate) a thin Si layer to bond to another Si wafer with an oxide layer as in the case of hydrogen ion implantation.

The former two methods have not resulted in satisfactory structures in terms of cost and/or bond strength and durability. The latter method involving hydrogen ion implantation has received some attention and has been considered advantageous over the former methods because the implantation energies required are less than 50% of that of oxygen ion implants and the dosage required is two orders of magnitude lower.

U.S. Pat. No. 5,374,564 discloses a process to obtain a single crystal silicon film on a substrate using a thermal process. A silicon wafer having a planar face is subject to the following steps: (i) implantation by bombardment of a face of the silicon wafer by means of ions creating a layer of gaseous micro-bubbles defining a lower region of the silicon wafer and an upper region constituting a thin silicon film; (ii) contacting the planar face of the silicon wafer with a rigid material layer (such as an insulating oxide material); and (iii) a third stage of heat treating the assembly of the silicon wafer and the insulating material at a temperature above that at which the ion bombardment was carried out. The third stage employs temperatures sufficient to bond the thin silicon film and the insulating material together, to create a pressure effect in the micro-bubbles, and to cause a separation between the thin silicon film and the remaining mass of the silicon wafer. (Due to the high temperature steps, this process does not work with lower cost glass or glass-ceramic substrates.)

U.S. Pat. No. 7,176,528 discloses a process that produces an SiOG structure. The steps include: (i) exposing a silicon wafer surface to hydrogen ion implantation to create a bonding surface; (ii) bringing the bonding surface of the wafer into contact with a glass substrate; (iii) applying pressure, temperature and voltage to the wafer and the glass substrate to facilitate bonding therebetween; and (iv) cooling the structure to a common temperature to facilitate separation of the glass substrate and a thin layer of silicon from the silicon wafer.

The resulting SOI structure just after exfoliation might exhibit excessive surface roughness (e.g., about 10 nm or greater), excessive silicon layer thickness (even though the layer is considered “thin”), and implantation damage of the silicon layer (e.g., due to the formation of an amorphized silicon layer). Some have suggested using chemical mechanical polishing (CMP) to further process the SOI structure after the thin silicon film has been exfoliated from the silicon material wafer. Disadvantageously, however, the CMP process does not remove material uniformly across the surface of the thin silicon film during polishing. Typical surface non-uniformities (standard deviation/mean removal thickness) are in the 3-5% range for semiconductor films. As more of the silicon film's thickness is removed, the variation in the film thickness correspondingly worsens.

The above shortcoming of the CMP process is especially a problem for some silicon on glass applications because, in some cases, as much as about 300-400 nm of material needs to be removed to obtain a desired silicon film thickness. For example, in thin film transistor (TFT) fabrication processes, a silicon film thickness in the 100 nm range or less has been desired. More recently, a silicon film thickness in the 10 nm range or less has been desired, which has not heretofore been achieved. The aforementioned processes for thinning the silicon film have not been demonstrated to produce a silicon film thickness in the 10 nm range.

Another problem with the CMP process is that it exhibits particularly poor results when rectangular SOI structures (e.g., those having sharp corners) are polished. Indeed, the aforementioned surface non-uniformities are amplified at the corners of the SOI structure compared with those at the center thereof. Still further, when large SOI structures are contemplated (e.g., for photovoltaic applications), the resulting rectangular SOI structures are too large for typical CMP equipment (which are usually designed for the 300 mm standard wafer size). Cost is also an important consideration for commercial applications of SOI structures. The CMP process, however, is costly both in terms of time and money. The cost problem may be significantly exacerbated if non-conventional CMP machines are required to accommodate large SOI structure sizes.

While wet etching processes have also been considered in thinning the silicon layer, such a process has not heretofore achieved a silicon film thickness in the 10 nm range. Further, the wet etching process includes are disadvantageous characteristic; namely, undercutting is caused by the isotropy of the etching procedure.

### SUMMARY

In accordance with one or more embodiments of the present invention, methods and apparatus of forming a TFT, include: subjecting an implantation surface of a donor single crystal semiconductor wafer to an ion implantation process to create an exfoliation layer of the donor semiconductor wafer; bonding the implantation surface of the exfoliation layer to a glass substrate using electrolysis; separating the exfoliation layer from the donor semiconductor wafer, thereby exposing a cleaved surface of the exfoliation layer; subjecting the cleaved surface of the exfoliation layer to a dry etching process to produce a single crystal semiconductor layer of about 5-20 nm thickness; and forming a thin film transistor in the thin semiconductor layer.

The dry etching process may be a reactive ion etching (RIE) process. For example, the RIE rate may be about 18-25 Angstroms/second, such as about 21.62 Angstroms/second. The dry etching process parameters may include: (i) a pressure of between about 10-25 mTorr; (ii) an RF power of about 50-100 W; (iii) a magnetic field strength of about 60-100 Gauss; (iv) a temperature of about 45-60 degrees C.; and/or (v) an atmosphere of about 70-90% nitrogen trifluoride and about 10-30% oxygen. In another embodiment, the RIE process parameters include: (i) a pressure of about 18 mTorr; (ii) an RF power of about 80 W; (iii) a magnetic field strength of about 80 Gauss; (iv) a temperature of about 55 degrees C.; and/or (v) an atmosphere of about 80% nitrogen trifluoride and about 20% oxygen.

The step of bonding may include: heating at least one of the glass substrate and the donor semiconductor wafer; bringing the glass substrate into direct or indirect contact with the donor semiconductor wafer through the exfoliation layer; and applying a voltage potential across the glass substrate and the donor semiconductor wafer to induce the bond.

A thin film transistor (TFT) in accordance with one or more embodiments of the present inventions includes: a glass or glass ceramic substrate; and a single crystal semiconductor layer in which the TFT is formed, the single crystal semiconductor layer being between about 5-20 nm thick and bonded through electrolysis to the glass or glass ceramic substrate.

The single crystal semiconductor layer may exhibit a thickness of about 10 nm or less, at least prior to formation of the TFT therein. Additionally or alternatively, the single crystal semiconductor layer may exhibit a surface roughness of less than about 25 Angstroms RMS, at least prior to formation of the TFT therein.

The TFT may be formed from a single crystal layer of silicon (Si), germanium-doped silicon (SiGe), silicon carbide (SiC), germanium (Ge), gallium arsenide (GaAs), GaP, and/or InP.

The single crystal semiconductor layer may be silicon and the TFT may be p-type and simulataneously exhibit a carrier mobility of greater than about 150 cm²/Vs, an off current of less than about 1 pA/um, and a sub-threshold slope of less than about 250 mV/dec. Alternatively, the TFT may be n-type and simulataneously exhibit a carrier mobility of greater than about 400 cm²/Vs, an off current of less than about 1 pA/um, and a sub-threshold slope of less than about 250 mV/dec.

Other aspects, features, advantages, etc. will become apparent to one skilled in the art when the description of the invention herein is taken in conjunction with the accompanying drawings.

### BRIEF DESCRIPTION OF THE DRAWINGS

For the purposes of illustrating the various aspects of the invention, there are shown in the drawings forms that are presently preferred, it being understood, however, that the invention is not limited to the precise arrangements and instrumentalities shown.

FIG. 1 is a block diagram illustrating the structure of a thin film transistor (TFT) formed as an SOG device in accordance with one or more embodiments of the present invention;

FIGS. 2-6 are block diagrams illustrating intermediate structures formed using processes of the present invention to produce a base SOG structure on which the TFT may be formed;

FIG. 7 is a block diagram illustrating a dry etching process for processing one of the intermediate structures to produce an SOG structure of ultra-thin characteristics;

FIGS. 8-9 are block diagrams illustrating intermediate structures formed using processes of the present invention to produce the TFT of FIG. 1 on the base SOG structure of FIG. 6;

FIG. 10 is a graph illustrating the surface roughness characteristics of the base SOG structure of FIG. 6 after a dry etching process;

FIGS. 11A-11B are graphs illustrating the surface roughness characteristics of the base SOG structure of FIG. 6 before and after a dry etching process, respectively; and

FIGS. 12-13 illustrate electrical characteristics of the TFT formed using one or more aspects of the present invention.

### DETAILED DESCRIPTION

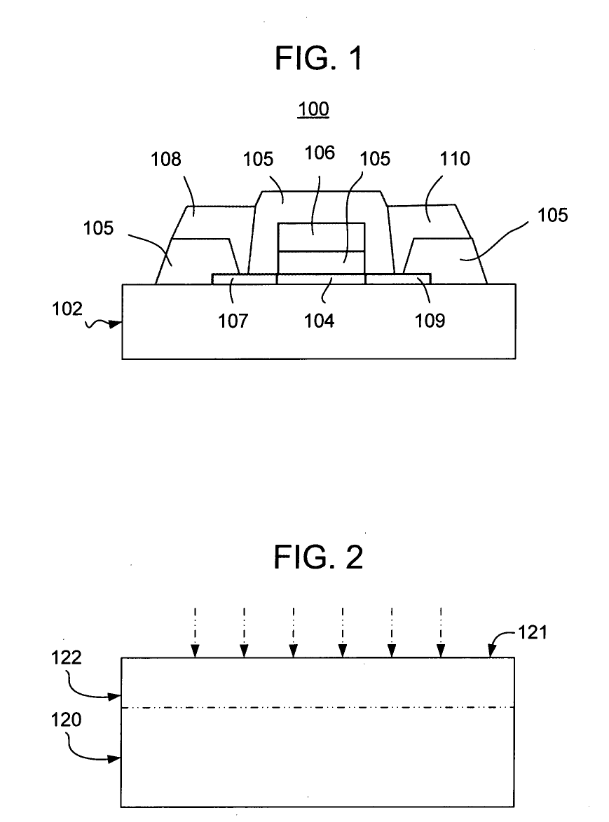

With reference to the drawings, wherein like numerals indicate like elements, there is shown in FIG. 1 a thin film transistor, TFT 100 formed on a SOG structure in accordance with one or more embodiments of the present invention. The TFT 100 includes a glass or glass ceramic substrate 102, and a semiconductor layer 104. The TFT 100 further includes insulation (e.g., oxide) regions 105, a gate contact 106, a source area 107 and source contact 108, and a drain area 109 and drain contact 110.

The TFT 100 has application for use in displays, including organic light-emitting diode (OLED) displays and liquid crystal displays (LCDs), integrated circuits, photovoltaic devices, etc.

As will be discussed in more detail later in this description, the semiconductor layer 104 is ultra-thin, e.g., having a thickness in the range of about 5-20 nm, particularly about 10 nm thick, at least prior to formation of the TFT components therein. Additionally or alternatively, the semiconductor layer 104 may exhibit a surface roughness of less than about 25 Angstroms RMS, at least prior to formation of the TFT components. These characteristics, alone or in combination, yield high quality TFTs with desirable electrical properties not heretofore achieved.

The semiconductor material of the layer 104 may be in the form of a substantially single-crystal material. The term “substantially” is used in describing the layer 104 to take account of the fact that semiconductor materials normally contain at least some internal or surface defects either inherently or purposely added, such as lattice defects or a few grain boundaries. The term substantially also reflects the fact that certain dopants may distort or otherwise affect the crystal structure of the semiconductor material.

For the purposes of discussion, it is assumed that the semiconductor layer 104 is formed from silicon. It is understood, however, that the semiconductor material may be a silicon-based semiconductor or any other type of semiconductor, such as, the III-V, II-IV, II-IV-V, etc. classes of semiconductors. Examples of these materials include: silicon (Si), germanium-doped silicon (SiGe), silicon carbide (SiC), germanium (Ge), gallium arsenide (GaAs), GaP, and InP.

The glass substrate 102 may be formed from an oxide glass or an oxide glass-ceramic. Although not required, the embodiments described herein may include an oxide glass or glass-ceramic exhibiting a strain point of less than about 1,000 degrees C. As is conventional in the glass making art, the strain point is the temperature at which the glass or glass-ceramic has a viscosity of 10^{14.6} poise (10^{13.6} Pa·s). As between oxide glasses and oxide glass-ceramics, the glasses may have the advantage of being simpler to manufacture, thus making them more widely available and less expensive.

By way of example, the glass substrate 102 may be formed from glass substrates containing alkaline-earth ions, such as, substrates made of CORNING INCORPORATED GLASS COMPOSITION NO. 1737 or CORNING INCORPORATED GLASS COMPOSITION NO. EAGLE 2000®. These glass materials have particular use in, for example, the production of liquid crystal displays.

The glass substrate may have a thickness in the range of about 0.1 mm to about 10 mm, such as in the range of about 0.5 mm to about 3 mm. For some SOG structures, insulating layers having a thickness greater than or equal to about 1 micron are desirable, e.g., to avoid parasitic capacitive effects which arise when standard SOG structures having a silicon/silicon dioxide/silicon configuration are operated at high frequencies. In the past, such thicknesses have been difficult to achieve. In accordance with the present invention, an SOG structure having an insulating layer thicker than about 1 micron is readily achieved by simply using a glass substrate 102 having a thickness that is greater than or equal to about 1 micron. A lower limit on the thickness of the glass substrate 102 may be about 1 micron.

In general, the glass substrate 102 should be thick enough to support the semiconductor layer 104 through the bonding process steps, as well as subsequent processing performed on the SOG structure to produce the TFT 100. Although there is no theoretical upper limit on the thickness of the glass substrate 102, a thickness beyond that needed for the support function or that desired for the ultimate TFT structure 100 might not be advantageous since the greater the thickness of the glass substrate 102, the more difficult it will be to accomplish at least some of the process steps in forming the TFT 100.

The oxide glass or oxide glass-ceramic substrate 102 may be silica-based. Thus, the mole percent of SiO₂ in the oxide glass or oxide glass-ceramic may be greater than 30 mole % and may be greater than 40 mole %. In the case of glass-ceramics, the crystalline phase can be mullite, cordierite, anorthite, spinel, or other crystalline phases known in the art for glass-ceramics. Non-silica-based glasses and glass-ceramics may be used in the practice of one or more embodiments of the invention, but are generally less advantageous because of their higher cost and/or inferior performance characteristics. Similarly, for some applications, e.g., for TFTs using SOG structures employing semiconductor materials that are not silicon-based, glass substrates which are not oxide based, e.g., non-oxide glasses, may be desirable, but are generally not advantageous because of their higher cost. As will be discussed in more detail below, in one or more embodiments, the glass or glass-ceramic substrate 102 is designed to match a coefficient of thermal expansion (CTE) of one or more semiconductor materials (e.g., silicon, germanium, etc.) of the layer 104 that are bonded thereto. The CTE match ensures desirable mechanical properties during heating cycles of the deposition process.

For certain applications, e.g., display applications, the glass or glass-ceramic 102 may be transparent in the visible, near UV, and/or IR wavelength ranges, e.g., the glass or glass ceramic 102 may be transparent in the 350 nm to 2 micron wavelength range.

Although the glass substrate 102 may be composed of a single glass or glass-ceramic layer, laminated structures can be used if desired. When laminated structures are used, the layer of the laminate closest to the semiconductor layer 104 may have the properties discussed herein for a glass substrate 102 composed of a single glass or glass-ceramic. Layers farther from the semiconductor layer 104 may also have those properties, but may have relaxed properties because they do not directly interact with the semiconductor layer 104. In the latter case, the glass substrate 102 is considered to have ended when the properties specified for a glass substrate 102 are no longer satisfied.

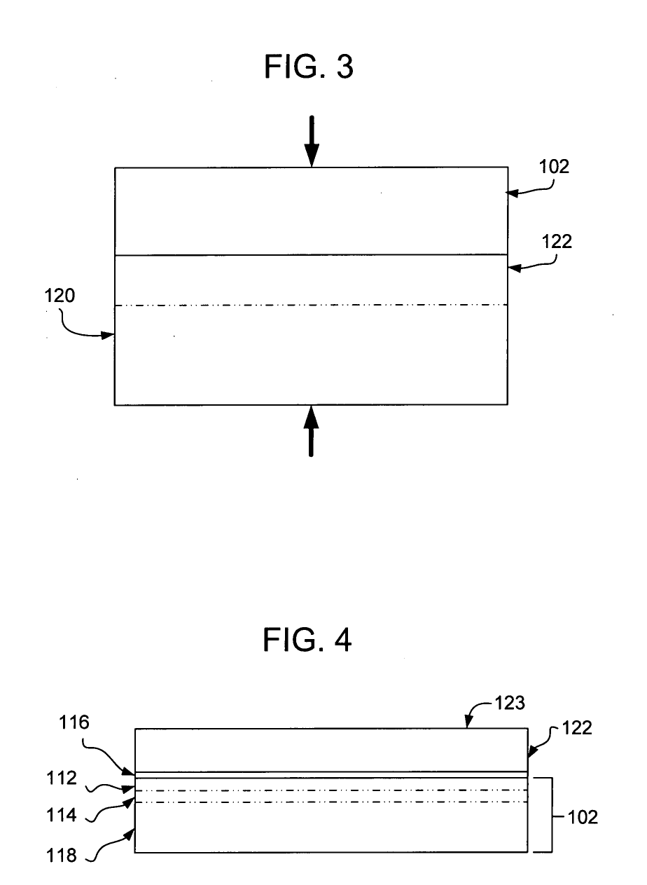

Reference is now made to FIGS. 2-6, which illustrate intermediate structures that may be formed in order to produce a base SOG structure 101 (FIG. 6) on which the TFT 100 may be formed. Turning first to FIG. 2, an implantation surface 121 of a donor semiconductor wafer 120 is prepared, such as by polishing, cleaning, etc. to produce a relatively flat and uniform implantation surface 121 suitable for bonding to the glass or glass-ceramic substrate 102. For the purposes of discussion, the semiconductor wafer 120 may be a substantially single crystal silicon wafer, although as discussed above any other suitable semiconductor conductor material may be employed.

An exfoliation layer 122 is created by subjecting the implantation surface 121 to one or more ion implantation processes to create a weakened region below the implantation surface 121 of the donor semiconductor wafer 120. Although the embodiments of the present invention are not limited to any particular method of forming the exfoliation layer 122, one suitable method dictates that the implantation surface 121 of the donor semiconductor wafer 120 may be subject to a hydrogen ion implantation process to at least initiate the creation of the exfoliation layer 122 in the donor semiconductor wafer 120. The implantation energy may be adjusted using conventional techniques to achieve a general thickness of the exfoliation layer 122, such as between about 300-500 nm. By way of example, hydrogen ion implantation may be employed, although other ions or multiples thereof may be employed, such as boron+hydrogen, helium+hydrogen, or other ions known in the literature for exfoliation. Again, any other known or hereinafter developed technique suitable for forming the exfoliation layer 122 may be employed without departing from the spirit and scope of the present invention.

The donor semiconductor wafer 120 may be treated to reduce, for example, the hydrogen ion concentration on the implantation surface 121. For example, the donor semiconductor wafer 120 may be washed and cleaned and the implantation donor surface 121 of the exfoliation layer 122 may be subject to mild oxidation. The mild oxidation treatments may include treatment in oxygen plasma, ozone treatments, treatment with hydrogen peroxide, hydrogen peroxide and ammonia, hydrogen peroxide and an acid or a combination of these processes. It is expected that during these treatments hydrogen terminated surface groups oxidize to hydroxyl groups, which in turn also makes the surface of the silicon wafer hydrophilic. The treatment may be carried out at room temperature for the oxygen plasma and at temperature between 25-150° C. for the ammonia or acid treatments.

With reference to FIGS. 3-4 the glass substrate 102 may be bonded to the exfoliation layer 122 using an electrolysis process. A suitable electrolysis bonding process is described in U.S. Pat. No. 7,176,528, the entire disclosure of which is hereby incorporated by reference. Portions of this process are discussed below. In the bonding process, appropriate surface cleaning of the glass substrate 102 (and the exfoliation layer 122 if not done already) may be carried out. Thereafter, the intermediate structures are brought into direct or indirect contact to achieve the arrangement schematically illustrated in FIG. 3. Prior to or after the contact, the structure(s) comprising the donor semiconductor wafer 120, the exfoliation layer 122, and the glass substrate 102 are heated under a differential temperature gradient. The glass substrate 102 may be heated to a higher temperature than the donor semiconductor wafer 120 and exfoliation layer 122. By way of example, the temperature difference between the glass substrate 102 and the donor semiconductor wafer 120 (and the exfoliation later 122) is at least 1 degree C., although the difference may be as high as about 100 to about 150 degrees C. This temperature differential is desirable for a glass having a coefficient of thermal expansion (CTE) matched to that of the donor semiconductor wafer 120 (such as matched to the CTE of silicon) since it facilitates later separation of the exfoliation layer 122 from the semiconductor wafer 120 due to thermal stresses.

Once the temperature differential between the glass substrate 102 and the donor semiconductor wafer 120 is stabilized, mechanical pressure is applied to the intermediate assembly. The pressure range may be between about 1 to about 50 psi. Application of higher pressures, e.g., pressures above 100 psi, might cause breakage of the glass substrate 102.

The glass substrate 102 and the donor semiconductor wafer 120 may be taken to a temperature within about +/−150 degrees C. of the strain point of the glass substrate 102.

Next, a voltage is applied across the intermediate assembly, for example with the donor semiconductor wafer 120 at the positive electrode and the glass substrate 102 the negative electrode. The intermediate assembly is held under the above conditions for some time (e.g., approximately 1 hour or less), the voltage is removed and the intermediate assembly is allowed to cool to room temperature.

With reference to FIG. 4, the donor semiconductor wafer 120 and the glass substrate 102 are then separated, which may include some peeling if they have not already become completely free, to obtain a glass substrate 102 with the relatively thin exfoliation layer 122 formed of the semiconductor material of the donor semiconductor layer 120 bonded thereto. The separation may be accomplished via fracture of the exfoliation layer 122 due to thermal stresses. Alternatively or in addition, mechanical stresses such as water jet cutting or chemical etching may be used to facilitate the separation.

The application of the voltage potential causes alkali or alkaline earth ions in the glass substrate 102 to move away from the semiconductor/glass interface further into the glass substrate 102. More particularly, positive ions of the glass substrate 102, including substantially all modifier positive ions, migrate away from the higher voltage potential of the semiconductor/glass interface, forming: (1) a reduced positive ion concentration layer 112 in the glass substrate 102 adjacent the semiconductor/glass interface; and (2) an enhanced positive ion concentration layer 112 of the glass substrate 102 adjacent the reduced positive ion concentration layer 112. This accomplishes a number of functions: (i) an alkali or alkaline earth ion free interface (or layer) 112 is created in the glass substrate 102; (ii) an alkali or alkaline earth ion enhanced interface (or layer) 112 is created in the glass substrate 102; (iii) an oxide layer 116 is created between the exfoliation layer 122 and the glass substrate 102; and (iv) the glass substrate 102 becomes very reactive and bonds to the exfoliation layer 122 strongly with the application of heat at relatively low temperatures.

In the example illustrated in FIG. 4, the intermediate structure resulting from the electrolysis process includes, in order: a bulk glass substrate 118 (in the glass substrate 102); the enhanced alkali or alkaline earth ion layer 114 (in the glass substrate 102); the reduced alkali or alkaline earth ion layer 112 (in the glass substrate 102); the oxide layer 116; and the exfoliation layer 122.

Some structural details of the various layers of the glass substrate 102 will now be described. The electrolysis process transforms the interface between the exfoliation layer 122 and the glass substrate 102 into an interface region comprising layer 112 (which is a positive ion depletion region) and layer 114 (which is a positive ion enhancement region). The interface region may also include one or more positive ion pile-up regions in the vicinity of the distal edge of the positive ion depletion layer 112.

The positive ion enhancement layer 114 is of enhanced oxygen concentration and has a thickness. This thickness may be defined in terms of a reference concentration for oxygen at a reference surface (not shown) above the glass substrate 102. The reference surface is substantially parallel to the bonding surface between the glass substrate 102 and the exfoliation layer 120 and is separated from that surface by a distance. Using the reference surface, the thickness of the positive ion enhancement layer 114 will typically satisfy the relationship:

T≦200 nm,

where T is the distance between bonding surface and a surface which is: (i) substantially parallel to bonding surface, and (ii) is the surface farthest from bonding surface for which the following relationship is satisfied:

CO(x)-CO/Ref≧50 percent, 0≦x≦T.

where CO(x) is the concentration of oxygen as a function of distance x from the bonding surface, CO/Ref is the concentration of oxygen at the above reference surface, and CO(x) and CO/Ref are in atomic percent.

Typically, T will be substantially smaller than 200 nanometers, e.g., on the order of about 50 to about 100 nanometers. It should be noted that CO/Ref will typically be zero, so that the above relationship will in most cases reduce to:

CO(x)≧50 percent, 0≦x≦T.

In connection with the positive ion depletion layer 112, the oxide glass or oxide glass-ceramic substrate 102 preferably comprises at least some positive ions that move in the direction of the applied electric field, i.e., away from the bonding surface and into the layer 114 of the glass substrate 102. Alkali ions, e.g., Li⁺¹, Na⁺¹, and/or K⁺¹ ions, are suitable positive ions for this purpose because they generally have higher mobilities than other types of positive ions typically incorporated in oxide glasses and oxide glass-ceramics, e.g., alkaline-earth ions. However, oxide glasses and oxide glass-ceramics having positive ions other than alkali ions, e.g., oxide glasses and oxide glass-ceramics having only alkaline-earth ions, can be used in the practice of the invention. The concentration of the alkali and alkaline-earth ions can vary over a wide range, representative concentrations being between 0.1 and 40 wt. % on an oxide basis. Preferred alkali and alkaline-earth ion concentrations are 0.1 to 10 wt. % on an oxide basis in the case of alkali ions, and 0-25 wt. % on an oxide basis in the case of alkaline-earth ions.

The electric field applied in the electrolysis process moves the positive ions (cations) further into the glass substrate 102 forming the positive ion depletion layer 108. The formation of the positive ion depletion layer 112 is especially desirable when the oxide glass or oxide glass-ceramic contains alkali ions, since such ions are known to interfere with the operation of semiconductor devices. Alkaline-earth ions, e.g., Mg⁺², Ca⁺², Sr⁺², and/or Ba⁺², can also interfere with the operation of semiconductor devices and thus the depletion region also preferably has reduced concentrations of these ions.

It has been found that the positive ion depletion layer 112 once formed is stable over time even if the SOG structure 100 is heated to an elevated temperature comparable to, or even to some extent higher than, that used in the electrolysis process. Having been formed at an elevated temperature, the positive ion depletion layer 112 is especially stable at the normal operating and formation temperatures of SOG structures. These considerations ensure that alkali and alkaline-earth ions will not diffuse back from the oxide glass or oxide glass-ceramic 102 into any semiconductor material that may be later applied to the glass substrate 102 directly or to the oxide layer 116, during use or further device processing, which is an important benefit derived from using an electric field as part of the electrolysis process.

The operating parameters needed to achieve the positive ion depletion layer 112 of a desired width and a desired reduced positive ion concentration for all of the positive ions of concern can be readily determined by persons skilled in the art from the present disclosure. When present, the positive ion depletion layer 112 is a characteristic feature of an SOG structure produced in accordance with one or more embodiments of the present invention.

Turning again to the process for forming the TFT 100, after separation the basic resulting structure of FIG. 4 includes the glass substrate 102 and the exfoliation layer 122 of semiconductor material bonded thereto. The cleaved surface 123 of the SOI structure just after exfoliation may exhibit excessive surface roughness, excessive silicon layer thickness, and implantation damage of the silicon layer (e.g., due to the formation of an amorphized silicon layer). In some cases, the amorphized silicon layer may be on the order of about 50-150 nm in thickness. In addition, depending on the implantation energy and implantation time, the thickness of the exfoliation layer 122 may be on the order of about 300-500 nm. The final thickness of the semiconductor layer 104 should be between about 5-20 nm, such as 10 nm.

Accordingly, with reference to FIG. 5, the cleaved surface 123 is subject to post processing, which may include subjecting the cleaved surface 123 to a dry etching process, indicated by the arrows showing removal of material. The dry etching process is intended to remove material 124 of the exfoliation layer 122, leaving the semiconductor layer 104. The characteristics of the dry etching process are such that the base SOG structure 101 (FIG. 6) includes the single crystal semiconductor layer 104 of about 5-20 nm thickness, particularly about 10 nm thickness. Additionally or alternatively, the semiconductor layer 104 may exhibit a surface roughness of less than about 25 Angstroms RMS, at least prior to formation of the TFT components.

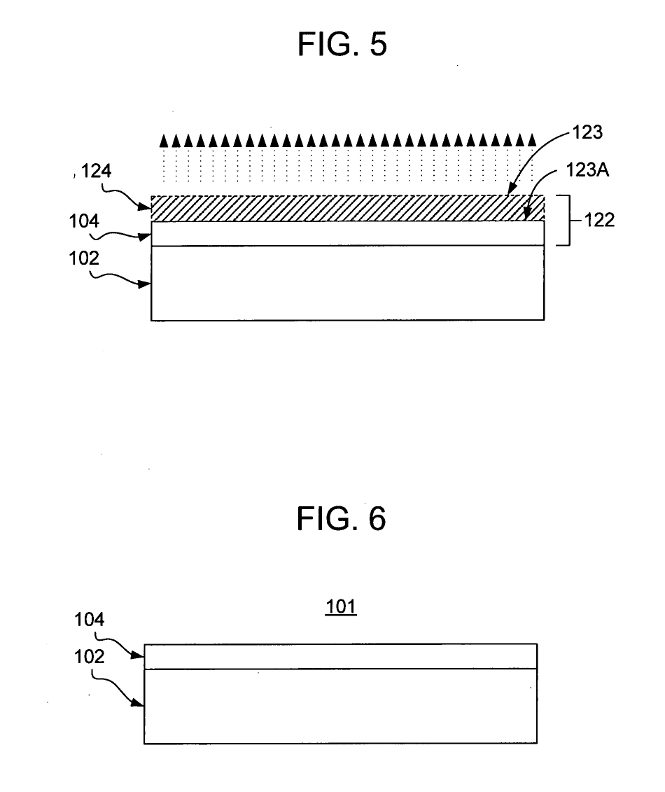

In one embodiment the etching process is a reactive ion etching (RIE) process as illustrated in FIG. 7. The dry etching process involves providing a chamber 150 in which an appropriate atmosphere in which an anisotropic etch (a uni-directional etch) is achieved. The chamber 150 includes first and second electrodes 152, 154 that create an electric field 156. The field 156 accelerates ions toward the surface 123 of the exfoliation layer 122. (Alternative processes may involve the alternative or additional use of a magnetic field to accelerate the ions.) A volume of plasma that contains both positively and negatively charged ions (in equal quantities) is produced from a gas that is pumped into the chamber 150. Among the gasses that may be employed, a mixture of NF₃ and oxygen is preferred when the semiconductor material of the exfoliation layer 122 is formed from silicon. Other gas chemistries may be used depending on the semiconductor material employed. This results in plasma with many fluorine (F−) ions. The fluorine ions are accelerated in the electric field and collide with the surface 123 of the exfoliation layer 122 and produce the etched surface 123A. A hard mask (not shown) may be used to protect certain areas from etching if desired.

The process parameters of the dry etching process include the atmospheric chemistry (the gas); atmospheric pressure; AC source power to the electrodes 152, 154; electric field strength (and/or magnetic field strength); temperature, etc. All of these parameters affect the etch rate and the ultimate surface quality after the etching process is complete. An RIE etching rate of about 18-25 Angstroms/second is suitable for the purposes of the invention, where an RIE rate of about 21.62 Angstroms/second has been demonstrated to achieve suitable surface quality on the semiconductor layer 104. The dry etching process parameters may include at least one of: (i) a pressure of between about 10-25 mTorr; (ii) an RF power of about 50-100 W; (iii) a magnetic field strength of about 60-100 Gauss; (iv) a temperature of about 45-60 degrees C.; and (v) an atmosphere of about 70-90% nitrogen tri-fluoride and about 10-30% oxygen. Through experimentation, the following etching process parameters have been shown to work: (i) a pressure of about 18 mTorr; (ii) an RF power of about 80 W; (iii) a magnetic field strength of about 80 Gauss; (iv) a temperature of about 55 degrees C.; and (v) an atmosphere of about 80% nitrogen tri-fluoride and about 20% oxygen.

Experiments have shown that the semiconductor layer 104 after thinning via the dry etching process may contain traces of N, F, H, and O—from the NF₃/O₂ gas used during the RIE thinning process. The Table below lists the surface composition of a 200 nm sample (area 1 and area 2) and a 50 nm SiOG sample (area 1 and area 2). Elements detected include carbon (C), nitrogen (N), oxygen (O), fluorine (F), and silicon (Si).

| Sample | C | N | O | F | Si |
|---|---|---|---|---|---|
| 200 nm area 1 | 14.6 | — | 35.9 | — | 49.5 |
| 200 nm area 2 | 13.3 | — | 36.0 | — | 50.7 |
| Average | 14.0 | | 35.9 | | 50.1 |
| 50 nm area 1 | 11.5 | 0.5 | 49.1 | 3.0 | 34.9 |
| 50 nm area 2 | 13.5 | 0.5 | 47.3 | 2.7 | 34.8 |
| Average | 12.5 | 0.5 | 48.2 | 2.8 | 34.8 |

The process may additionally or alternatively include subjecting the etched surface 123A of the semiconductor layer 104 to polishing. The intent of the polishing step is to remove additional material from the semiconductor layer 104 by polishing the etched surface 123A down to a polished surface. The polishing step may include using polishing (or buffing) equipment to buff the etched surface 123A using a silica based slurry or similar material known in the art in the semiconductor industry. This polishing process may be a deterministic polishing technique as known in the art. Following the polishing step, the remaining semiconductor layer 104 may be substantially thinner and/or smoother than would otherwise be obtained by etching alone.

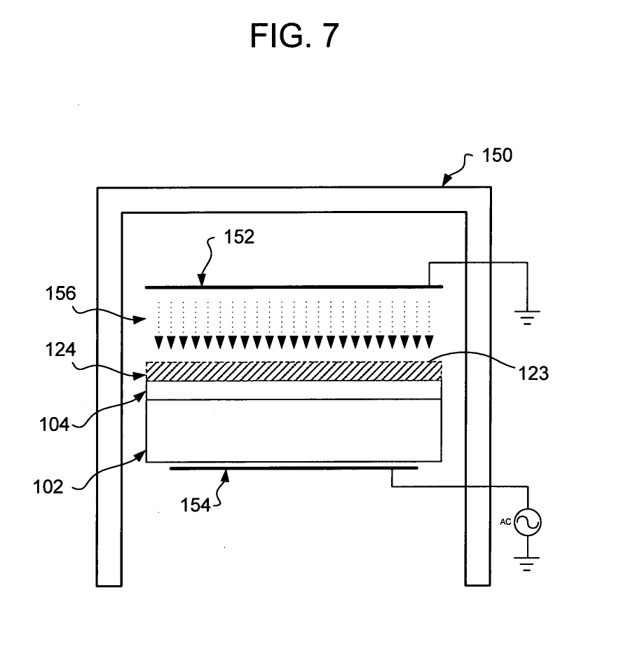

With reference to FIGS. 8-9, the base SOG structure 101 may be further processed to form the TFT 100 using known procedures. For example, with reference to FIG. 8, the semiconductor layer 104 may be subject to oxide deposition (e.g., silicon dioxide) 105A followed by the deposition of a metal layer 106A. With reference to FIG. 9, the oxide layer 105A and the metal layer 106A may be patterned using (e.g., etching techniques) and doping using ion shower techniques (and or any of the other known techniques). Finally, inter-layers, contact holes, and metal contacts may be disposed using known fabrication techniques to produce the TFT 100 of FIG. 1.

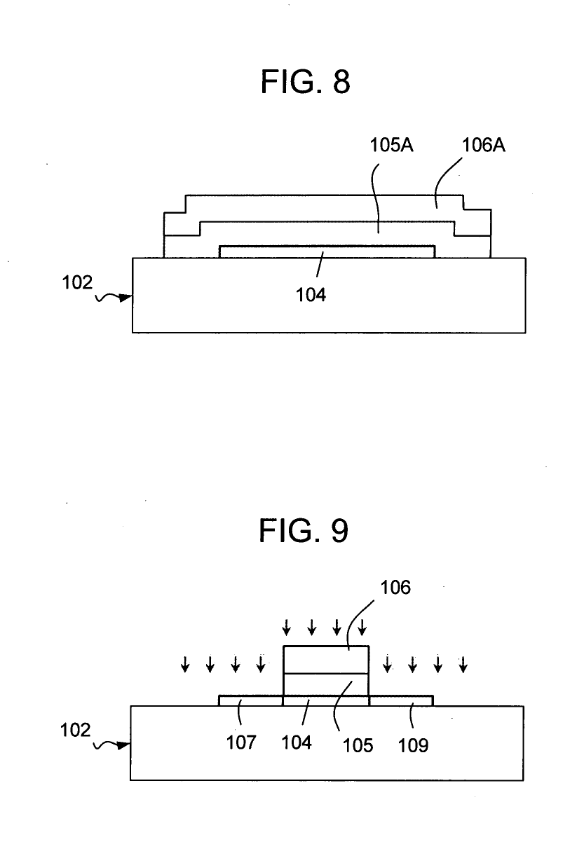

With reference to FIG. 10, the aforementioned thinning process was carried out on a base SOG structure 101 employing single crystal silicon, which yielded a surface roughness of less than about 25 Angstroms RMS, particularly 24.4 Angstroms RMS, where the average roughness was 18.2 Angstroms.

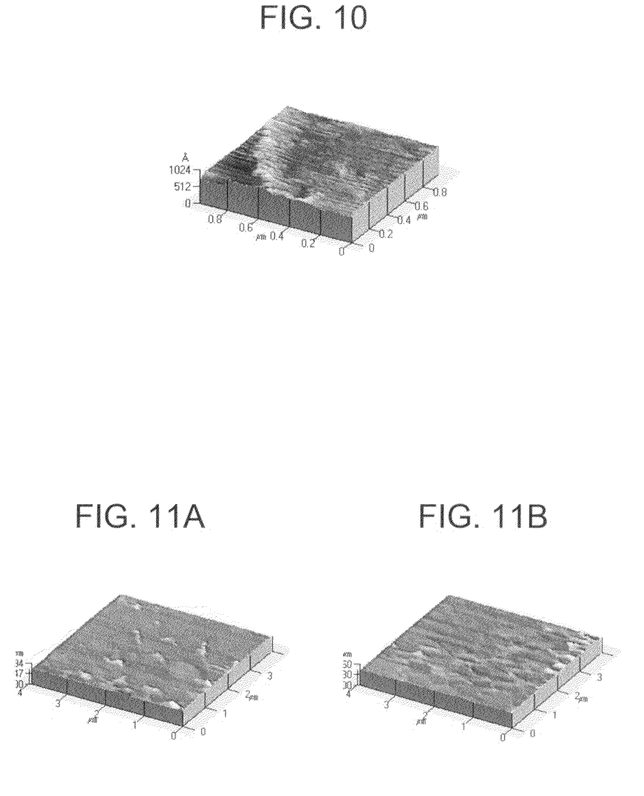

With reference to FIGS. 11A-11B, the aforementioned thinning process was carried out on a single crystal silicon layer (or wafer) of 200 nm thickness, and having the following surface roughness characteristics: 1200 Angstrom peak-to-peak, 55.2 Angstrom RMS, and 27.2 Angstroms average. After an RIE thinning process commensurate with one or more embodiments disclosed herein, the single crystal silicon layer exhibited a 50 nm in thickness, and the following surface roughness characteristics: 117 Angstrom peak-to-peak, 42.5 Angstrom RMS, and 31.4 Angstroms average.

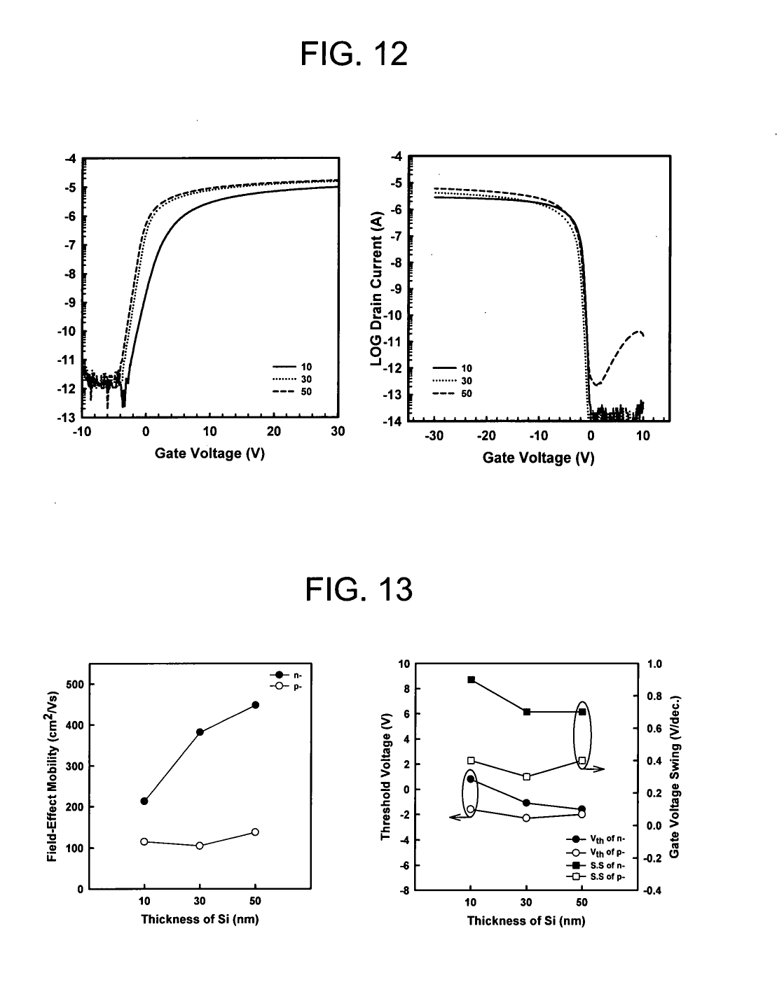

With reference to FIG. 12, the off current of a TFT of the present invention (10 nm silicon layer) is shown compared with the off currents of respective TFTs employing 30 nm and 50 nm silicon layer thicknesses. The off current of the TFT with the 10 nm silicon layer may exhibit an off current of less than about 1 pA/um. With reference to FIG. 13, the field effect mobility and the threshold voltage of a TFT of the present invention (10 nm silicon layer) is shown compared with the characteristics of respective TFTs employing 30 nm and 50 nm silicon layer thicknesses. The field effect mobility of the TFT with the 10 nm silicon layer (e.g., p-type carrier mobility) of greater than about 150 cm²/Vs may be achieved. Further a sub-threshold slope of less than about 250 mV/dec may also be achieved. An n-type TFT may exhibit an n-type carrier mobility of greater than about 400 cm2/Vs; an off current of less than about 1 pA/um; and/or a sub-threshold slope of ideally less than about 250 mV/dec.

Although the invention herein has been described with reference to particular embodiments, it is to be understood that these embodiments are merely illustrative of the principles and applications of the present invention. It is therefore to be understood that numerous modifications may be made to the illustrative embodiments and that other arrangements may be devised without departing from the spirit and scope of the present invention as defined by the appended claims.

1. A thin film transistor (TFT), comprising:
a glass or glass ceramic substrate; and
a single crystal semiconductor layer in which the TFT is formed, the single crystal semiconductor layer being between about 5-20 nm thick and bonded through electrolysis to the glass or glass ceramic substrate.

2. The TFT of claim 1, wherein the single crystal semiconductor layer exhibits a thickness of about 10 nm or less, at least prior to formation of the TFT therein.

3. The TFT of claim 1, wherein the single crystal semiconductor layer exhibits a surface roughness of less than about 25 Angstroms RMS, at least prior to formation of the TFT therein.

4. The TFT of claim 1, wherein:
the single crystal semiconductor layer is silicon; and
the TFT is p-type and simulataneously exhibits a carrier mobility of greater than about 150 cm²/Vs, an off current of less than about 1 pA/um, and a sub-threshold slope of less than about 250 mV/dec.

5. The TFT of claim 1, wherein:
the single crystal semiconductor layer is silicon; and
the TFT is n-type and simulataneously exhibits a carrier mobility of greater than about 400 cm²/Vs, an off current of less than about 1 pA/um, and a sub-threshold slope of less than about 250 mV/dec.

6. The TFT of claim 1, wherein the single crystal semiconductor layer is taken from the group consisting of: silicon (Si), germanium-doped silicon (SiGe), silicon carbide (SiC), germanium (Ge), gallium arsenide (GaAs), GaP, and InP.

7. The TFT of claim 1, wherein:
the glass or glass ceramic substrate includes, in order, a bulk layer, an enhanced positive ion concentration layer, a reduced positive ion concentration layer, where the enhanced positive ion concentration layer contains substantially all modifier positive ions from the reduced positive ion concentration layer as a result of migration; and
a conductive or semiconductive oxide layer is located between the reduced positive ion concentration layer of the substrate and the single crystal semiconductor layer.

8. A method of forming a thin film transistor (TFT), comprising:
subjecting an implantation surface of a donor single crystal semiconductor wafer to an ion implantation process to create an exfoliation layer of the donor semiconductor wafer;
bonding the implantation surface of the exfoliation layer to a glass substrate using electrolysis;
separating the exfoliation layer from the donor semiconductor wafer, thereby exposing a cleaved surface of the exfoliation layer;
subjecting the cleaved surface of the exfoliation layer to a dry etching process to produce a single crystal semiconductor layer of about 5-20 nm thickness; and
forming a thin film transistor in the thin semiconductor layer.

9. The method of claim 8, wherein the dry etching process is a reactive ion etching (RIE) process.

10. The method of claim 8, wherein the RIE rate is about 18-25 Angstroms/second.

11. The method of claim 10, wherein the RIE rate is about 21.62 Angstroms/second.

12. The method of claim 8, wherein the dry etching process parameters include at least one of: (i) a pressure of between about 10-25 mTorr; (ii) an RF power of about 50-100 W; (iii) a magnetic field strength of about 60-100 Gauss; (iv) a temperature of about 45-60 degrees C.; and (v) an atmosphere of about 70-90% nitrogen trifluoride and about 10-30% oxygen.

13. The method of claim 8, wherein the dry etching process parameters include: (i) a pressure of about 18 mTorr; (ii) an RF power of about 80 W; (iii) a magnetic field strength of about 80 Gauss; (iv) a temperature of about 55 degrees C.; and (v) an atmosphere of about 80% nitrogen trifluoride and about 20% oxygen.

14. The method of claim 8, wherein the step of bonding includes:
heating at least one of the glass substrate and the donor semiconductor wafer;
bringing the glass substrate into direct or indirect contact with the donor semiconductor wafer through the exfoliation layer; and
applying a voltage potential across the glass substrate and the donor semiconductor wafer to induce the bond.

15. The method of claim 14, further comprising maintaining the contact, heat, and voltage such that: (i) an oxide layer forms on the substrate between the donor semiconductor wafer and the substrate; and (ii) positive ions of the substrate, including substantially all modifier positive ions, migrate away from the higher voltage potential of the donor semiconductor wafer, forming: (1) a reduced positive ion concentration layer in the substrate adjacent the donor semiconductor wafer; and (2) an enhanced positive ion concentration layer of the substrate adjacent the reduced positive ion concentration layer;

16. The method of claim 8, wherein the donor semiconductor wafer is taken from the group consisting of: silicon (Si), germanium-doped silicon (SiGe), silicon carbide (SiC), germanium (Ge), gallium arsenide (GaAs), GaP, and InP.
